(19) United States
(12) Patent Application Publication
(10) Pub. No.: US 2008/0112214 A1
(43) Pub. Date: May 15, 2008

(54) Electronic assembly having magnetic tunnel junction voltage sensors and method for forming the same

(76) Inventors: Young Sir Chung, Chandler, AZ (US); Robert W. Baird, Gilbert, AZ (US); Mark A. Durlam, Chandler, AZ (US); Pon Sung Ku, Gilbert, AZ (US)

Correspondence Address: INGRASSIA FISHER & LORENZ, P.C. (FS), 7150 E. CAMELBACK ROAD, SUITE 325, SCOTTSDALE, AZ, 85251, US

(21) Appl. No.: 11/590,276

(22) Filed: Oct. 30, 2006

(51) Int. Cl. G11C 11/00; G11C 11/14; G11C 7/02

(52) U.S. Cl. 365/158; 365/209; 365/171

(57) ABSTRACT

A method and assembly for sensing a voltage with a memory cell (88) is provided. The memory cell includes first and second electrodes (96,112), first and second ferromagnetic bodies (104,108) positioned between the first and second electrodes and an insulating body (94) positioned between the first and second ferromagnetic bodies. The first electrode is electrically connected to a first portion of a microelectronic assembly (47). The second electrode is electrically connected to a second portion of the microelectronic assembly. The voltage across the first and second portions of the microelectronic assembly is determined based on an electrical resistance of the memory cell. The memory cell may be a magnetoresistive random access memory (MRAM) cell. In one embodiment, the memory cell is a magnetic tunnel junction (MTJ) memory cell.

### FIELD OF THE INVENTION

The present invention generally relates to a microelectronic assembly and a method for forming a microelectronic assembly, and more particularly relates to a microelectronic assembly having magnetic tunnel junction voltage sensors.

### BACKGROUND OF THE INVENTION

Integrated circuits are formed on semiconductor substrates, or wafers. The wafers are then sawed into microelectronic dies (or “dice”), or semiconductor chips, with each die carrying a respective integrated circuit. Each semiconductor chip is mounted to a package or carrier substrate using either wirebonding or “flip-chip” connections. The packaged chip is then typically mounted to a circuit board, or motherboard, before being installed in a system, such as an electronic or a computing system.

“Smart” power integrated circuits are single-chip devices capable of generating and providing power in a controlled and intelligent manner. Smart power integrated circuits typically include a power circuit component, an analog control component, and a digital logic component. Smart power integrated circuits may also include one or more sensors which can be used to measure or detect physical parameters such as position, motion, force, acceleration, temperature, pressure and so forth. Such sensors can be used, for example, to control the output power in response to changing operating conditions.

Voltage sensing is often incorporated into power integrated circuit (IC) design to protect the circuit, device, and/or system, particularly in integrated circuits that implement smart power and magnetoresistive random access memory (MRAM) designs. Existing voltage sensors suffer from various limitations, such as excessive size and weight, inadequate sensitivity and/or dynamic range, cost, reliability and other factors. Thus, there continues to be a need for improved voltage sensors that can be easily integrated with semiconductor devices and integrated circuits, as well as the manufacturing methods thereof.

Accordingly, it is desirable to provide an improved sensor and method, adaptable for measuring various physical parameters. It is further desirable that the improved sensor and method convert the physical parameter being measured into an electrical signal. It would be desirable to provide sensors which exhibit improved measurement performance and which can be integrated in a three-dimensional architecture. Other desirable features and characteristics of the invention will become apparent from the subsequent detailed description and the appended claims, taken in conjunction with the accompanying drawings and the foregoing technical field and background.

### BRIEF DESCRIPTION OF THE DRAWINGS

The various embodiments will hereinafter be described in conjunction with the following drawings, wherein like numerals denote like elements, and

FIG. 1 is a top plan view of a semiconductor substrate;

FIG. 2 is a cross-sectional side view of a portion of the semiconductor substrate of FIG. 1 having an integrated circuit formed thereon;

FIG. 3 is a schematic plan view of an electronic assembly according to one embodiment of the present invention;

FIG. 4 is a schematic cross-sectional view of the electronic assembly of FIG. 3;

FIG. 5 is a cross-sectional side view of the electronic assembly if FIG. 3;

FIG. 6 is an isometric view of an magnetic tunnel junction (MTJ) cell within the electronic assembly of FIG. 5; and

FIG. 7 is a cross-sectional side view of the MTJ cell of FIG. 6 taken along line 7-7.

### DETAILED DESCRIPTION OF THE INVENTION

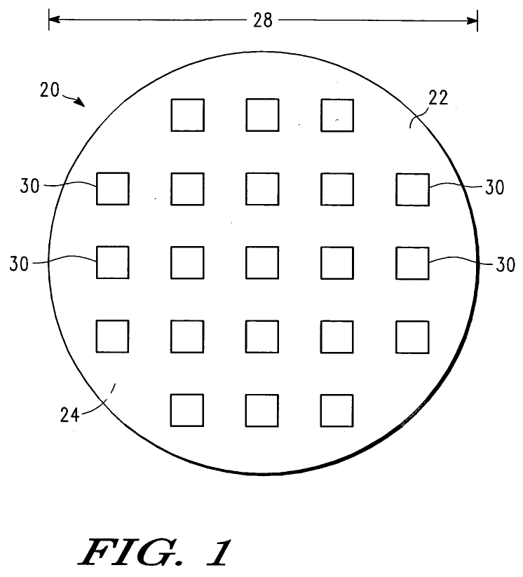

The following detailed description is merely exemplary in nature and is not intended to limit the invention or application and uses of the invention. Furthermore, there is no intention to be bound by any expressed or implied theory presented in the preceding technical field, background, brief summary, or the following detailed description. It should also be noted that FIGS. 1-7 are merely illustrative and may not be drawn to scale.

FIG. 1 to FIG. 7 illustrate a microelectronic assembly and a method for sensing a voltage across portions of a microelectronic assembly, according to one embodiment of the present invention. A memory cell, having first and second electrodes, is provided. The memory cell also includes first and second ferromagnetic bodies positioned between the first and second electrodes and an insulating body positioned between the first and second ferromagnetic bodies. The first electrode is electrically connected to a first portion of the microelectronic assembly. The second electrode is electrically connected to a second portion of the microelectronic assembly. The voltage across the first and second portions of the microelectronic assembly is determined based on an electrical resistance of the memory cell. The memory cell may be a magnetoresistive random access memory (MRAM) cell. In one embodiment, the memory cell is a magnetic tunnel junction (MTJ) memory cell.

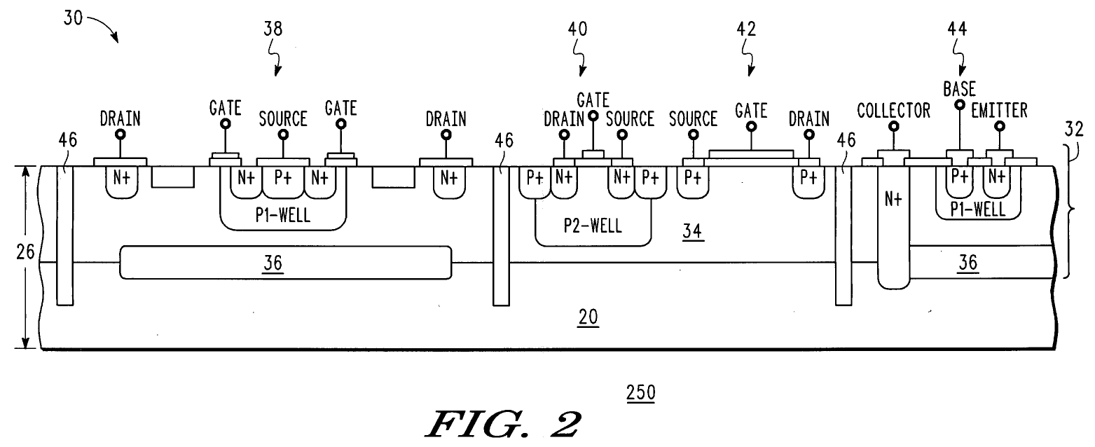

Referring to FIGS. 1 and 2, there is illustrated a semiconductor substrate 20. The semiconductor substrate 20 is made of a semiconductor material, such as gallium arsenide (GaAs), gallium nitride (GaN), or silicon (Si). The substrate 20 has an upper surface 22, a lower surface 24, and a thickness 26 of, for example, between approximately 300 and 1000 microns. The semiconductor material of the substrate 20 may be of a first conductivity type, or doped with a first dopant type (e.g., P-type). The substrate 20 may be a semiconductor wafer with a diameter 28 of, for example, approximately 150, 200, or 300 millimeters. As illustrated specifically in FIG. 1, the substrate 20 is divided into multiple dies 30, or “dice.” As will be described in greater detail below, each die 30 may have an at least partially formed integrated circuit 32 thereon. Although the following process steps may be shown as being performed on only one die 30, or a small portion of the substrate 20; it should be understood that each of the steps may be performed on substantially the entire substrate 20, or multiple dice 30, simultaneously. Furthermore, although not shown, it should be understood that the processing steps described below may be facilitated by the deposition and removal of multiple additional processing layers, such as photoresist, as is commonly understood.

FIG. 2 illustrates one of the dies 30, or other portion of the substrate 20, along with an integrated circuit 32 formed thereon. In one embodiment of the present invention, the integrated circuit 32 is a “smart” power integrated circuit, as is commonly understood. As shown, the integrated circuit 32 (and/or the substrate 20) includes an N-type doped epitaxial layer 34, with N+ buried layers 36 formed therein, and a power metal-oxide semiconductor field-effect transistor (MOSFET) 38, complementary metal-oxide semiconductor (CMOS) devices (N-MOSFET 40 and P-MOSFET 42), and a bipolar device 44. The integrated circuits 32 may also include other various active and passive components, such as diodes, resistors, capacitors, inductors, fuses, anti-fuses, and memory devices, as well as at least one metal layer, with additional metal layers being added, to increase the circuit density and to enhance circuit performance. As shown in FIG. 2, various N-type and P-type contact regions and wells are formed using known semiconductor processing methods, such as implantation and diffusion. In the depicted embodiment, the substrate 20 also includes isolation components 46, such as shallow trench isolation (STI) regions, which may be formed using an oxidation and/or a trenching process.

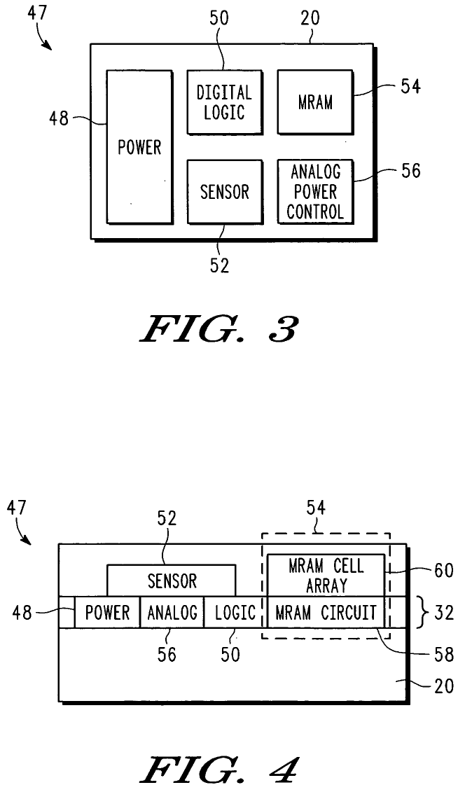

FIG. 3 schematically illustrates an electronic, or microelectronic, assembly (or integrated circuit device) 47, according to one embodiment of the present invention. In the depicted embodiment, the assembly 47 includes a power circuit component 48, a digital logic component 50, a sensor architecture 52, an magnetoresistive random access memory (MRAM) architecture 54, and an analog power control component 56. Although not shown in FIG. 3, the integrated circuit 32 may form one more of the components of the assembly 47, and also include additional components as necessary to satisfy the needs of the particular application. In practice, some of these functional components may be coupled together to enable cooperative operation. For example, the power circuit component 48, the digital logic component 50, the sensor architecture 52, and the analog power control component 56 may cooperate to form the smart power architecture for the integrated circuit device 47. In this regard, these components (individually or in any combination thereof) are also referred to herein as “smart power components.” The MRAM architecture 54, however, need not be coupled to the other components and may be configured to function as an independent subsystem of the integrated circuit 32 and/or the microelectronic assembly 47.

In one practical embodiment of the invention, the power circuit component 48 includes one or more power MOSFET devices that are configured to operate at high voltages and high currents. Alternate embodiments may employ different power devices and techniques for the power circuit component 48. The digital logic component 50 may be realized with CMOS transistors or any suitable digital logic arrangement. The digital logic component 50 is configured to carry out the digital operations that support the smart power architecture of the integrated circuit 32. The analog power control component 56 includes analog circuit components configured to support the smart power architecture of the integrated circuit 32. The analog power control component 56 may include, for example, resistors, capacitors, inductors, MOSFETs, bipolar devices, and/or other analog circuit elements.

The sensor architecture 52 is generally configured to sense physical, electrical, magnetic, environmental, and/or other conditions for the integrated circuit 32. In this example, the integrated circuit 32 uses the quantity, characteristic, parameter, or phenomena detected by the sensor architecture 52 to regulate, control, manage, or monitor the output power generated by the power circuit component 48. In this regard, the sensor architecture 52 may employ one or more sensors or sensor components, such as an environmental condition sensor (e.g., a temperature sensor, a humidity sensor, a light sensor, a radiation sensor, or an electromagnetic sensor), an electromechanical sensor (e.g., a transducer), a mechanical sensor (e.g., a vibration sensor, an accelerometer, a stress/strain sensor), a magnetic field sensor, an electrical attribute sensor (e.g., a voltage sensor, a current sensor, an impedance or resistance sensor, a temperature sensor, a capacitance sensor, or an inductance sensor.)

FIG. 4 further schematically illustrates the microelectronic assembly 47 including an exemplary topological arrangement of the functional components thereof. In the embodiment shown, the MRAM architecture 54 and the smart power architecture (including the power circuit component 48, the digital logic component 50, the sensor architecture 52, and the analog power control component 56) are formed on substrate 20. The MRAM architecture 54 includes an MRAM circuit component 58 and an MRAM cell array 60 coupled to and formed above the MRAM circuit component 58. The MRAM circuit component 58 may include any number of elements or features that support the operation of the MRAM architecture 54, including for example, switching transistors, input/output circuitry, a decoder, comparators, and sense amplifiers.

In one exemplary embodiment of the invention, the microelectronic assembly 47 is manufactured using a modular process technology having a front end fabrication process (i.e., including front end semiconductor processing steps) and a back end fabrication process (i.e., including back end semiconductor processing steps), as is commonly understood. In this context, the front end fabrication process is completed before the back end process is initiated. As used herein, the front end fabrication process is associated with the formation of elements or features using “front end layers,” which may be N-type and/or P-type doped regions within and/or on the semiconductor substrate 20, dielectric layers, or other layers, while the back end fabrication process is associated with the formation of elements or features using “back end layers,” which may be metal or conductive layers, dielectric layers, MTJ core layers (as described below), and/or other layers. Thus, the front end layers are located in or on the substrate 20, and the back end layers are located above the front end layers. In practice, the front end and back end fabrication processes may utilize, for example, masking, reactive ion etching (RIE), physical sputtering, damascene patterning, physical vapor deposition, electroplating, and chemical vapor (CVD), low pressure chemical vapor (LPCVD), and/or plasma enhanced chemical vapor deposition (PECVD) techniques. For example, the integrated circuit 32 may be manufactured using CMOS, bipolar, or other suitable fabrication processes.

Referring again to FIG. 4, the microelectronic assembly 47 may include additional layers (e.g., metal layers, dielectric layers, and/or a ground plane) than those shown. In the depicted embodiment, the integrated circuit 32 includes the power circuit component 48, the analog power control component 56, the digital logic component 50, and the MRAM circuit component 58, which are formed during the front end fabrication process. The sensor architecture 52 (which may include one or more sensor) and the MRAM cell array 60 are formed during the back end fabrication process. In practice, the front end and back end fabrication processes are modules in the MRAM fabrication process employed to create the MRAM architecture 54. Thus, the manufacture of the integrated circuit 32 utilizes the existing MRAM fabrication process for purposes of the smart power architecture. In this manner, at least a portion of the smart power architecture and at least a portion of the MRAM architecture 54 can be concurrently formed by the chosen MRAM fabrication process.

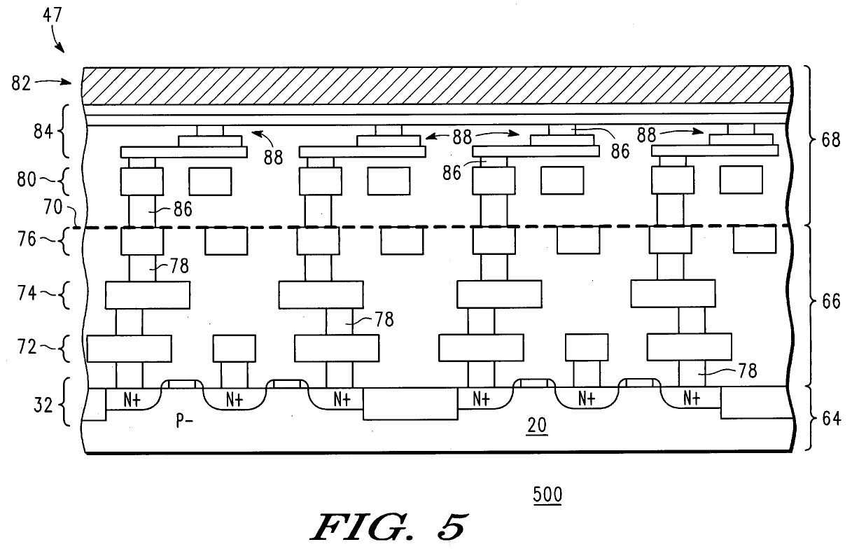

FIG. 5 illustrates the microelectronic assembly 47 in greater detail. The assembly 47 includes the substrate 20, front end layers 64 (including the integrated circuit 32) formed in or on substrate 20, first (or lower) back end layers 66 and second (or upper) back end layers 68 formed above the front end layers 64. Dashed line 70 represents an imaginary dividing line between a first back end fabrication process (i.e., forming the first back end layers 66) and a second back end fabrication process (i.e., forming the second back end layers 68), as is will be appreciated by one skilled in the art.

Still referring to FIG. 5, in one embodiment, the first back end layers 66 of the electronic assembly 47 include a first metal layer 72, a second metal layer 74, a third metal layer 76, various intervening insulating layers (or interlayer dielectrics (ILD)), and first conductive vias 78 and traces routed between layers. The second back end layers 68 include a fourth metal layer 80, a fifth metal layer 82, a MTJ core layer (or region) 84, intervening insulating layers, and second conductive vias 86 routed between layers. As described in greater detail below, the MTJ core layer 84 may include additional layers formed during the formation of the second back end layers 68. The various metals layers 72, 74, 76, 80, and 82 and the conductive vias 78 and 86 may be, for example, made of copper, aluminum, and/or tungsten and formed using plating and/or sputtering. The insulating layers may be, for example, made of silicon oxide (SiO₂), silicon nitride (SiN), tetraethylorthosilicate (TEOS), and/or borophosphosilicate tetraethylorthosilicate (BPTEOS) and formed using CVD, LPCVD, and/or PECVD.

Referring to FIGS. 3, 4, and 5 in combination, in the depicted embodiment, the power circuit component 48, the analog power control component 56, the digital logic component 50, and the MRAM circuit component 58 are formed in the first back end layers 66 from the first metal layer 72, the second metal layer 74, and/or the metal layer 76. The sensor architecture 52 and the MRAM. cell array 60 are formed in the second back end layers 68 from the fourth metal layer 80, the fifth metal layer 82, and/or the MTJ core layer 84. The MRAM cell array 60 includes a plurality of conductive traces (or bit lines) formed on the fifth metal layer 82, a plurality of conductive traces (or digit lines) formed on the fourth metal layer 80, and an array of MTJ cells 88 formed within the MTJ core layer 84 between the fourth metal layer 80 and the fifth metal layer 82.

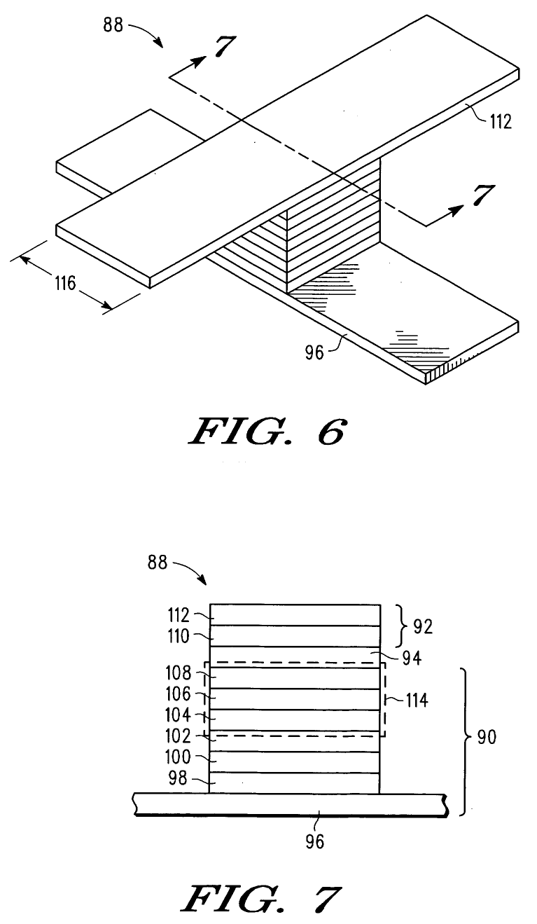

FIGS. 6 and 7 illustrate one of the MTJ cells 88 in greater detail. In the depicted embodiment, the MTJ cell 88 includes a first electrode stack 90, a second electrode stack 92, and an insulating tunnel barrier layer 94 between the first and second electrodes stacks 90 and 92. The first electrode stack 90, in one embodiment, includes a first (or base) electrode (or electrode layer) 96, a seed layer 98, a template layer 100, an antiferromagnetic pinning layer 102, a pinned ferromagnetic layer 104, a metallic coupling layer 106, and an amorphous fixed ferromagnetic layer 108.

The first electrode layer 96 may be made from a single layer, or multiple layers, of conductive material. The seed layer 98 may be formed of any material suitable for seeding the subsequent formation of the antiferromagnetic pinning layer 102, as described in more detail below. The seed layer 98 may be, for example, made of tantalum (Ta) or a tantalum nitride (TaN_{X}), which is formed by reactive sputtering or plasma and/or ion beam nitridation of a thin layer of tantalum (e.g., less than 100 or 50 angstroms). The template layer 100 may include a nickel iron (NiFe) alloy, a nickel iron cobalt (NiFeCo) alloy, ruthenium (Ru), tantalum (Ta), aluminum (Al), and/or any other suitable material. The antiferromagnetic pinning layer 102 is formed over the seed layer 98 and/or the template layer 100. The antiferromagnetic pinning layer 102 may be formed from any suitable antiferromagnetic material, but preferably comprises a manganese alloy, with the general composition MnX, where X is preferably one or more materials selected from a group of platinum (Pt), palladium (Pd), nickel (Ni), iridium (Ir), osmium (Os), ruthenium (Ru), or iron (Fe).

The pinned ferromagnetic layer 104 is formed on and exchange coupled with the underlying antiferromagnetic pinning layer 102, which pins the magnetic moment of the pinned ferromagnetic layer 104 in one direction. The pinned ferromagnetic layer 104 is crystalline in structure and may be formed of, for example, a cobalt iron alloy, such as CoFe or CoFeX, where X includes boron (B), tantalum (Ta), hafnium (Hf), or carbon (C).

The amorphous fixed ferromagnetic layer 108 is formed on the metallic coupling layer 106, which overlies the pinned ferromagnetic layer 104. As used herein, the term “amorphous” shall mean a material or materials in which there is no long-range crystalline order such as that which would give rise to a readily discernable peak using normal x-ray diffraction measurements or a discernable pattern image using electron diffraction measurements. In one embodiment of the invention, amorphous fixed ferromagnetic layer 108 may be formed of an alloy of cobalt (Co), iron (Fe), and boron (B). For example, the amorphous fixed layer 108 may be formed of an alloy comprising 71.2% at. cobalt, 8.8% at. iron, and 20% at. boron. This composition is a CoFe alloy with boron added and may be represented as (Co₈₉Fe₁₁)₈₀B₂₀. However, it will be appreciated that any other suitable alloy composition, such as CoFeX (where X may be one or more of tantalum, hafnium, boron, carbon, and the like), or alloys comprising cobalt and/or iron, may be used to form amorphous fixed layer 30. The metallic coupling layer 106 may be formed of any suitable material that serves to antiferromagnetically couple the crystalline pinned layer 104 and the amorphous fixed layer 108, such as ruthenium, rhenium, osmium, rhodium, or alloys thereof, but is preferably formed of ruthenium. The metallic coupling layer 106, the crystalline pinned layer 104, and the amorphous fixed layer 108 create a synthetic antiferromagnet (SAF) structure 114. The antiferromagnetic coupling of the SAF structure 114 provided through the metallic coupling layer 106 improves the stability of the MTJ cell 88 in applied magnetic fields. Additionally, by varying the thickness of the ferromagnetic layers 104 and 108, magnetostatic coupling to the free layer 110 can be offset and the hysteresis loop can be centered.

The lack of substantial crystalline grain boundaries within the amorphous fixed layer 108 facilitates the growth of the tunnel barrier layer 94 with a reduced surface roughness compared to the tunnel barrier layer 94 being grown over a crystalline or polycrystalline fixed layer. The smoother surfaces of the tunnel barrier layer 94 improve the magnetoresistance of the MTJ cell 88. In addition, the crystalline pinned layer 104 provides sufficient antiferromagnetic coupling strength so that the SAF structure 114 is stable in an external magnetic field. Accordingly, the amorphous fixed layer 108 and the crystalline pinned layer 104 serve to improve performance, reliability, and manufacturability of the MJT cell 88.

Still referring to FIGS. 6 and 7, the second electrode multilayer stack 92 comprises a free ferromagnetic layer 110 and a protective second electrode (or electrode layer) 112. The second electrode layer 112 is, for example, formed of any suitable conductive material, such as tantalum (Ta). The second electrode layer 112 may comprise more than one layer of material, such as, for example, a layer of tantalum nitride overlying a layer of tantalum. The magnetic moment of the free ferromagnetic layer 110 is not substantially fixed or pinned by exchange coupling and is substantially free to rotate in the presence of an applied magnetic field. The free ferromagnetic layer 110 may have an amorphous or crystalline structure and may be formed of any suitable alloy composition, such as CoFeX (where X may be boron, tantalum, hafnium, carbon, and the like), or alloys comprising nickel and iron, or alloys comprising cobalt, nickel, and iron. In one embodiment of the invention, the free ferromagnetic layer 110 includes a single layer of NiFeCo. In another embodiment of the invention, free ferromagnetic layer 34 is an SAF structure comprising, for example, two layers of ferromagnetic material, such as NiFe, separated by a coupling layer of conducting material such as ruthenium, rhenium, osmium, rhodium, alloys thereof, and the like. In yet another embodiment of the invention, the free ferromagnetic layer 34 is a multilayer SAF structure comprising, for example, four layers of ferromagnetic material, such as NiFe, CoFe, or a combination thereof, separated by coupling layers such as ruthenium, rhenium, osmium, rhodium, alloys thereof, and the like. For example in a multilayer free layer, four magnetic layers, as described above, would be each be separated by a SAF layer, or a total of three SAF layers in a multilayer free layer stack.

The insulating tunnel barrier layer 94 preferably is formed of a dielectric material and more preferably is formed of an aluminum oxide (AlOₓ). The tunnel barrier layer 94 may have any suitable thickness, but preferably has a thickness in the range of from about 7 to about 15 angstroms. The layers of first multilayer stack 90, second multilayer stack 92, and tunnel barrier layer 94 may be formed by any suitable deposition process, such as, for example, ion beam deposition, physical vapor deposition (PVD), molecular beam epitaxy (MBE), and the like. Each component of the MTJ cell 88 may have, for example, a width 116 of between 1.0 and 1.25 microns (μm). Each MTJ cell 88 may thus cover an area of, for example, between 1.0 and 1.5 μm².

Although not specifically illustrated, the first electrode 96 is electrically connected to a first portion of the integrated circuit 32 through the vias 78 and 86 and various conductors within the first and second back end layers 66 and 68. The second electrode is similarly connected to a second portion of the integrated circuit 32. The MTJ cells may be arranged such that multiple MTJ cells 88 are connected in series (or in parallel) between the first and second portions of the integrated circuit 32.

Although not shown, contact openings (or multiple contact openings) may then be formed through at least the second back end, or build up, layers 68. Electrical contacts may then be formed in or over the openings to provide an electrical connection to the microelectronic assembly 47. The formation of such contacts may substantially complete the formation of the microelectronic 47 assembly. After final processing steps, the substrate 20 may be sawed into the individual microelectronic dice 30 (shown in FIG. 1), or semiconductor chips, packaged, and installed in various systems.

During operation, the smart power integrated circuit device 47 provides the various functional capabilities indicated in FIGS. 3 and 4 and described above, such as voltage regulation, power MOSFETs, input signal conditioning, transient protection, system diagnostics, and control. In order to perform these functions, the device 47 may be required to monitor the electrical voltage across particular portions of the integrated circuit 32, or other portions of the microelectronic assembly. Such monitoring may be required for feedback control, over-current protection, and/or circuit operation shutdown. As the circuit is operated, electrical current flows from the first portion of the integrated circuit 32, through the MTJ cells 88, and into the second portion of the integrated circuit 32. The MTJ cells 88 exhibit a strongly negative voltage coefficient, and as such, the electrical resistance of the MTJ cells 88 decreases as the voltage across the first and second portions of the integrated circuit 32 increases. The voltage is determined by monitoring the output resistance of the MTJ cells 88.

In one embodiment, each MTJ cell 88 can sense a voltage up to approximately 1.8 V. However, the size and shape of the components of the MTJ cells 88 described above may be varied to alter the voltage handling capability of the individual MTJ cells 88. Additionally, the voltage sensing range can be varied by connecting multiple cells 88 is series and/or parallel between the various portions of the integrated circuit.

One advantage of method and system described above is that, because of the strongly negative voltage coefficient of the MTJ memory cells, the MTJ cells provide superior sensitivity as voltage sensors. Another advantage is that, because of the high resistance of the MTJ cells, the amount of current required is minimized and power dissipation is reduced, thus increasing the efficiency of the microelectronic assembly. A further advantage is that because the MTJ cells can be arranged in series, the voltage sensing range of the assembly can be adjusted. The MTJ voltage sensors also demonstrate excellent voltage isolation capability, as they are formed during backend processing, further improving the operation of the assembly. Additionally, because of the small size the MTJ cells, as well as the formation thereof during back end processing, the space occupied by the voltage sensing components, particularly on the semiconductor substrate, is minimized. Thus, the overall size of the assembly is reduced and performance is even further improved.

The invention provides a method for sensing a voltage across first and second portions of a microelectronic assembly. A memory cell is provided. The memory cell has first and second electrodes, first and second ferromagnetic bodies positioned between the first and second electrodes, and an insulating body positioned between the first and second ferromagnetic bodies. The first portion of the microelectronic assembly is electrically connected to the first electrode. The second portion of the microelectronic assembly is electrically connected to the second electrode. The voltage is determined based on an electrical resistance of the memory cell.

The memory cell may be a magnetoresistive random access memory (MRAM) cell. The first ferromagnetic body may have a fixed magnetic orientation, and the second ferromagnetic body may have a free magnetic orientation. The memory cell may be a magnetic tunnel junction (MTJ) memory cell.

The microelectronic assembly may include an integrated circuit. The first portion of the microelectronic assembly may be a first portion of the integrated circuit, and the second portion of the microelectronic assembly may be a second portion of the integrated circuit.

The memory cell may be formed within the microelectronic assembly. The microelectronic assembly may also include a substrate. The integrated circuit may be formed on the substrate, and the memory cell may be formed over the integrated circuit.

When the voltage is a first voltage, the electrical resistance may have a first value. When the voltage is a second voltage, the electrical resistance may have a second value. The second voltage may be greater than the first voltage, and the first value of the resistance may be greater than the second value of the resistance.

The invention also provides a method for constructing a microelectronic assembly. An integrated circuit is formed over a semiconductor substrate. The integrated circuit has first and second portions. At least one memory cell is formed over the integrated circuit. The at least one memory cell has first and second electrodes, first and second ferromagnetic bodies positioned between the first and second electrodes, and an insulating body positioned between the first and second ferromagnetic bodies. The first electrode is electrically connected to the first portion of the integrated circuit, and the second electrode is electrically connected to the second portion of the integrated circuit. The integrated circuit is configured to conduct a current through the at least one memory cell and determine a voltage across the first and second portions of the integrated circuit based on an electrical resistance of the at least one memory cell.

The at least one memory cell may be a magnetoresistive random access memory (MRAM) cell. The first ferromagnetic body may have a fixed magnetic orientation, and the second ferromagnetic body may have a free magnetic orientation. The at least one memory cell may be a magnetic tunnel junction (MTJ) memory cell.

The integrated circuit may be formed using front end semiconductor processing steps, and the at least one memory cell may be formed using back end semiconductor processing steps.

The method may also include forming a memory cell array over the integrated circuit. The memory cell array may include a plurality of MTJ memory cells. The integrated circuit may also include at least one of a power circuit component, an analog control component, and a digital logic component.

The invention further provides a microelectronic assembly including a substrate, an integrated circuit having first and second portions formed over the substrate, a plurality of memory cells formed over the substrate, each memory cell having first and second electrodes, first and second ferromagnetic bodies positioned between the first and second electrodes, and an insulating body positioned between the first and second ferromagnetic bodies, the first electrode of each memory cell being electrically connected to the first portion of the integrated circuit and the second electrode of each memory cell being electrically connected to the second portion of the integrated circuit. The integrated circuit is configured to conduct a current through the at least one memory cell and determine a voltage across the first and second portions of the integrated circuit based on an electrical resistance of the at least one memory cell.

The plurality of memory cells may be magnetoresistive random access memory (MRAM) cell and jointly form an MRAM memory cell array. The MRAM memory cell array may be formed over the integrated circuit.

At least some of the plurality of memory cells may be electrically connected in series between the first portion of the integrated circuit and the second portion of the integrated circuit. The plurality of memory cells may be magnetic tunnel junction (MTJ) memory cells.

The integrated circuit may also include an MRAM circuit component. The integrated circuit may also include at least one of a power circuit component, an analog control component, and a digital logic component.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

What is claimed is:

1. A method for sensing a voltage across first and second portions of a microelectronic assembly comprising:
providing a memory cell having first and second electrodes, first and second ferromagnetic bodies positioned between the first and second electrodes, and an insulating body positioned between the first and second ferromagnetic bodies;
electrically connecting the first portion of the microelectronic assembly to the first electrode;
electrically connecting the second portion of the microelectronic assembly to the second electrode; and
determining the voltage based on an electrical resistance of the memory cell.

2. The method of claim 1, wherein the memory cell is a magnetoresistive random access memory (MRAM) cell.

3. The method of claim 2, wherein the first ferromagnetic body has a fixed magnetic orientation and the second ferromagnetic body has a free magnetic orientation.

4. The method of claim 3, wherein the memory cell is a magnetic tunnel junction (MTJ) memory cell.

5. The method of claim 4, wherein the microelectronic assembly comprises an integrated circuit and wherein the first portion of the microelectronic assembly is a first portion of the integrated circuit and the second portion of the microelectronic assembly is a second portion of the integrated circuit.

6. The method of claim 5, wherein the memory cell is formed within the microelectronic assembly, the microelectronic assembly further comprises a substrate, and wherein the integrated circuit is formed on the substrate and the memory cell is formed over the integrated circuit.

7. The method of claim 6, wherein when the voltage is a first voltage, the electrical resistance has a first value, and when the voltage is a second voltage, the electrical resistance has a second value, the second voltage being greater than the first voltage and the first value of the resistance being greater than the second value of the resistance.

8. A method for constructing a microelectronic assembly comprising:
forming an integrated circuit over a semiconductor substrate, the integrated circuit having first and second portions; and
forming at least one memory cell over the integrated circuit, the at least one memory cell having first and second electrodes, first and second ferromagnetic bodies positioned between the first and second electrodes, and an insulating body positioned between the first and second ferromagnetic bodies, the first electrode being electrically connected to the first portion of the integrated circuit and the second electrode being electrically connected to the second portion of the integrated circuit;
wherein the integrated circuit is configured to conduct a current through the at least one memory cell and determine a voltage across the first and second portions of the integrated circuit based on an electrical resistance of the at least one memory cell.

9. The method claim 8, wherein the at least one memory cell is a magnetoresistive random access memory (MRAM) cell.

10. The method of claim 9, wherein the first ferromagnetic body has a fixed magnetic orientation and the second ferromagnetic body has a free magnetic orientation.

11. The method of claim 10, wherein the at least one memory cell is a magnetic tunnel junction (MTJ) memory cell.

12. The method of claim 11, wherein the integrated circuit is formed using front end semiconductor processing steps and the at least one memory cell is formed using back end semiconductor processing steps.

13. The method of claim 12, further comprising forming a memory cell array over the integrated circuit, the memory cell array comprising a plurality of MTJ memory cells.

13. The method of claim 11, wherein the integrated circuit further comprises at least one of a power circuit component, an analog control component, and a digital logic component.

14. A microelectronic assembly comprising:
a substrate;
an integrated circuit formed over the substrate, the integrated circuit having first and second portions; and
a plurality of memory cells formed over the substrate, each memory cell having first and second electrodes, first and second ferromagnetic bodies positioned between the first and second electrodes, and an insulating body positioned between the first and second ferromagnetic bodies, the first electrode of each memory cell being electrically connected to the first portion of the integrated circuit and the second electrode of each memory cell being electrically connected to the second portion of the integrated circuit;
wherein the integrated circuit is configured to conduct a current through the at least one memory cell and determine a voltage across the first and second portions of the integrated circuit based on an electrical resistance of the at least one memory cell.

15. The microelectronic assembly of claim 14, wherein the plurality of memory cells are a magnetoresistive random access memory (MRAM) cell and jointly form an MRAM memory cell array.

16. The microelectronic assembly of claim 15, wherein the MRAM memory cell array is formed over the integrated circuit.

17. The microelectronic assembly of claim 16, wherein at least some of the plurality of memory cells are electrically connected in series between the first portion of the integrated circuit and the second portion of the integrated circuit.

18. The microelectronic assembly of claim 17, wherein the plurality of memory cells are magnetic tunnel junction (MTJ) memory cells.

19. The microelectronic assembly of claim 18, wherein the integrated circuit further comprises an MRAM circuit component.

20. The microelectronic assembly of claim 19, wherein the integrated circuit further comprises at least one of a power circuit component, an analog control component, and a digital logic component.
